(19) United States
(12) Patent Application Publication
(10) Pub. No.: US 2024/0266800 A1
(43) Pub. Date: Aug. 8, 2024

(54) Control of laser sources

(71) Applicant: SIGNIFY HOLDING B.V., EINDHOVEN (NL)

(72) Inventors: KARNEKUMAR ARULANDU, BREDA (NL); MATTHIAS WENDT, WÜRSELEN (DE); OLEXANDR VALENTYNOVYCH VDOVIN, MAARHEEZE (NL)

(21) Appl. No.: 18/565,135

(22) PCT Filed: May 30, 2022
(86) PCT No.: PCT/EP2022/064574

§ 371 Date: Nov. 29, 2023

(30) Foreign Application Priority Data
Jun. 1, 2021 (EP) 21177036.7

(51) Int. Cl. H01S 5/062; H01S 5/042; H01S 5/06; H01S 5/068; H01S 5/183; H05B 45/325

(52) U.S. Cl. CPC H01S 5/06216; H01S 5/0428; H01S 5/0617; H01S 5/06804; H01S 5/06808; H01S 5/183; H05B 45/325

(57) ABSTRACT

A laser circuit has a current source for delivering current to a laser device. A pulse width modulation laser drive current is used, and the amplitude and duty cycle of the laser drive current is set in dependence on an estimated junction temperature. In this way efficiency may be kept high for different operating temperatures and a desired optical output power.

### FIELD OF THE INVENTION

This invention relates to the control of laser sources.

### BACKGROUND OF THE INVENTION

It is commonly known that lasers require a drive current higher than the lasing threshold current in order to emit substantial optical output power. Below this lasing current, the efficiency in photon generation is very low such that the lasing current can mainly be seen as a major contribution to losses in efficiency. From an efficiency point of view, it is therefore beneficial to maximize the drive current such that the drive current is significantly higher than the lasing current.

The maximum drive current for maximum efficiency strongly depends on the junction temperature of a laser, such as a vertical-cavity surface-emitting laser, VCSEL. An earlier rollover (after a local maxima) of the optical output power as a function of the forward current can be expected at elevated junction temperatures, and such maximum efficiency is junction temperature dependent. The main goal of a laser illumination source is to ensure that a specific amount of light is emitted at the highest possible efficiency.

It would therefore be desirable to enable a constant output power to be provided (corresponding to the desired amount of light) at all operating conditions, giving different junction temperatures.

### SUMMARY OF THE INVENTION

The invention is defined by the claims.

According to examples in accordance with an aspect of the invention, there is provided a laser circuit, comprising:
a laser device;
a current source adapted to provide a current to the laser device, wherein the current has an amplitude and a duty cycle;
a controller for controlling the current source; and
a sensor arrangement for monitoring a signal enabling a junction temperature of the laser device to be estimated,
wherein the controller is adapted to:
   estimate a junction temperature of the laser device;
   set the amplitude of the current to the laser device in dependence on the junction temperature, and
   set the duty cycle of the current to the laser device in dependence on a required power for the laser device.

This laser circuit uses both the amplitude and duty cycle of a pulse width modulation laser drive current to enable operation at a high efficiency at different junction temperatures. By enabling operation at a high efficiency, not only is energy saved but also power dissipation problems are mitigated.

An increase in temperature in particular results in the controller implementing a decrease in amplitude of the current to shift to the efficient operating point and an increase in duty cycle to maintain a similar average current.

It is known that the average output power of a laser can be controlled by adapting a duty cycle of a PWM control signal or by adapting the drive current. Lowering the drive current to lower the power is not beneficial because the efficiency is impaired by the increased contribution of the lasing current, as explained above. Lowering the output power of a laser solely by controlling the duty-cycle of a PWM control signal is also not desirable as the drive current amplitude for maximum efficiency is temperature dependent.

The invention thereby combines these two approaches to enable high efficiency operation as well as maintaining a desired output.

The current source may comprise a switching element coupled in parallel with the laser device or in series with the laser device, wherein the switching element is arranged to control the duty cycle of the current to the laser device.

This may function as a shunting switch or a series switch. Instead, the current source may itself generate a pulse width modulation output current.

The controller is for example adapted to control the current amplitude and the duty-cycle of the pulse width modulation laser drive current achieve a desired efficiency and a desired optical output power. The desired optical output power may for example be constant.

The controller is for example adapted to control the current amplitude and the duty cycle of the pulse width modulation laser drive current to operate at an amplitude corresponding to a maximum efficiency and to operate at a duty cycle to deliver the desired optical output power. By enabling operation at a maximum efficiency, not only is energy saved but also power dissipation problems are mitigated. The point of maximum efficiency may be estimate based on known characteristics of the laser device or the efficiency may be monitored to provide feedback control.

The sensor arrangement may comprise a temperature sensor for measuring a case temperature of the laser device. The case temperature may be used to provide an estimate of the laser device junction temperature. This may for example use thermal information relating to the device and the device casing.

The sensor arrangement may additionally or alternatively comprise an optical flux sensor for measuring an optical output power. The measured optical output power may be used in combination with data which characterizes the optical output power as a function of the junction temperature for the particular device. This characterization information could for example have been obtained during the manufacturing process of the laser device itself or during the assembly and factory calibration of the overall laser circuit.

A current amplitude measurement device may also be provided for measuring a laser device current. This provides a feedback measurement of the drive current. The laser is driven with a current according to the setting of the current source, but measuring the current enables an error in the current setting to be detected.

The controller may be further adapted to determine the output power of the laser and to set the amplitude and duty cycle of the laser drive current further in dependence on the output power.

In this way a feedback control loop is provided to enable the output power to be maintained at a desired constant level, instead of assuming an output power based on the drive conditions.

The laser device may comprise a vertical cavity surface emitting laser. Alternatively, the laser device may comprise one or more laser diodes.

The laser circuit is for example a lighting circuit for delivering a constant light output power.

The invention also provides a method of controlling a laser device, comprising:
estimating a junction temperature of the laser device;
setting an amplitude of a pulse width modulation laser drive current in dependence on the junction temperature;
setting a duty cycle of the pulse width modulation laser drive current in dependence of a required power for the laser device, and
delivering the laser driver current to the laser device.

The method may comprise controlling setting the current amplitude and the duty cycle of the pulse width modulation laser drive current to achieve a desired efficiency and a desired optical output power.

The method may then comprise setting the current amplitude and the duty cycle of the pulse width modulation laser drive current to operate at an amplitude corresponding to a maximum efficiency and to operate at a duty cycle to deliver the desired optical output power.

The invention also provides a computer program comprising computer program code means which is adapted, when said program is run on a computer, to implement the method defined above.

These and other aspects of the invention will be apparent from and elucidated with reference to the embodiment(s) described hereinafter.

### BRIEF DESCRIPTION OF THE DRAWINGS

For a better understanding of the invention, and to show more clearly how it may be carried into effect, reference will now be made, by way of example only, to the accompanying drawings, in which:

FIG. 1 shows the output power as a function of forward current as measured for a particular VCSEL;

FIG. 2 shows an example of a PWM drive current with a variable current amplitude and duty cycle for different junction temperatures;

FIG. 3 shows a simplified block diagram of a laser circuit.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should be understood that the Figures are merely schematic and are not drawn to scale. It should also be understood that the same reference numerals are used throughout the Figures to indicate the same or similar parts.

The invention provides a laser circuit having a current source for delivering current to a laser device. A pulse width modulation laser drive current is used, and the amplitude and duty cycle of the laser drive current is set in dependence on an estimated junction temperature. In this way, efficiency may be kept high for different operating temperatures and a desired optical output power.

The invention may be applied to any laser which exhibits a different function of output power versus drive current at different junction temperatures. This applies to lasers and laser diodes. By way of example only, the invention will be explained using measurements taken for a vertical cavity surface emitting laser, VCSEL.

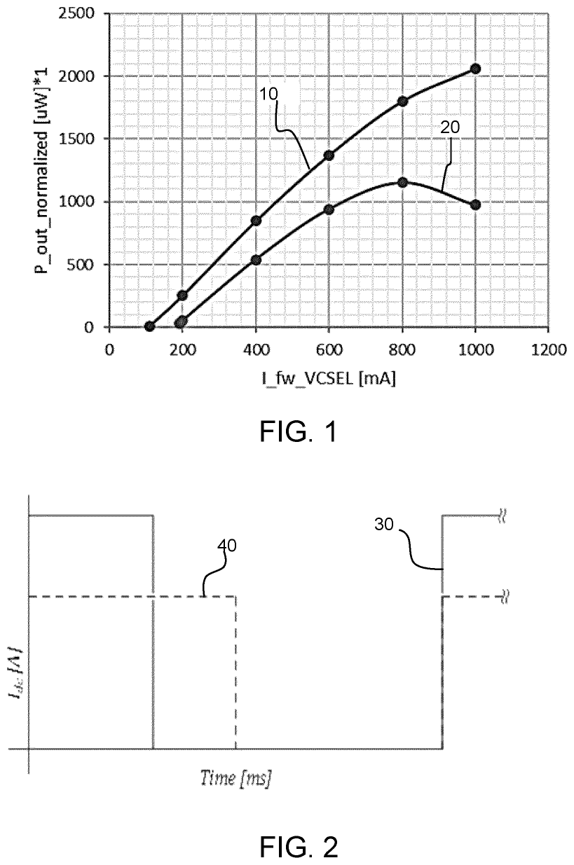

FIG. 1 shows the optical output power (y-axis) as a function of forward current (x-axis) as measured for a particular VCSEL. Plot 10 represents the optical output power as a function of forward current at a case temperature of 20° C., and plot 20 shows the output power of the VCSEL as a function of forward current at a case temperature of 60° C.

For more accurate evaluation, the actual junction temperature can be determined by:

$$\\ {T}_{j} = {P}_{diss} {R}_{th , ( j - c )} + {T}_{c}$$

where Tⱼ is the junction temperature of the VCSEL; P_{diss}, the dissipated power; R_{th(j-c)}, the thermal resistance between junction and case; T_{c} is the case temperature.

FIG. 1 is instead based only on measurement of the case temperature.

When looking at the major efficiency aspect of the VCSEL, it can be roughly stated that:

$$\\ {η}_{VCSEL} = \frac{{P}_{opt}}{{P}_{elec}}$$

where η_{VCSEL} is the efficiency of the VCSEL, Pₒₚₜ is the optical output power of the VCSEL, and P_{elec} is the electrical power applied to the VCSEL.

As can be seen in FIG. 1, the output power for drive current levels below the lasing threshold current remains near zero. Current levels above the lasing current result in proportionally more output power. At higher current levels, the proportionality between input current and output power is lost and the curve starts to flatten out, indicating reduced efficiency at higher currents, for example beyond 600 mA drive current for plot 10. At elevated case temperatures, there will even be a rollover effect, for example as can be seen after 800 mA in plot 20, such that the VCSEL output power even becomes less for an increase of forward current.

Thus, it can be concluded that VCSELs have a maximum efficiency of operation which is dependent on the junction temperature. The drop in efficiency beyond a particular drive current is related to the carrier concentration in the junction, which is itself junction temperature dependent. Thus, the efficiency of the peak has been found to be strongly related to the junction temperature.

A laser lighting application typically requires a constant predetermined average optical output power. With this constraint, a highest efficiency can be achieved by maximizing the forward current such that the portion of lasing current is small compared to the forward current, while not exceeding the reduced efficiency operation due to a high current density within the junction.

Practically, this maximum forward current can be expected to be slightly beyond the linear proportional slope (of output power vs. input current), hence where the slope starts to reduce slightly. Thus, based on known characteristic curves for the laser device, a point of (estimated) maximum efficiency may be determined based on a measurement or estimation of junction temperature.

The desired average output power can then be obtained by setting the duty cycle of the PWM control signal.

Depending on the application, the case temperature and thereby indirectly also the junction temperature may vary, hence even for a given application, it is desirable to adapt the control of the laser device in dependence on temperature.

FIG. 2 shows an example of a PWM drive current with a variable current amplitude and duty cycle, to maximize efficiency of the VCSEL output power at two different junction temperatures. Plot 30 is for a junction temperature of 25° C. and plot 40 is for a junction temperature of 60° C.

As can be seen, at a higher junction temperature, the current amplitude is reduced but the duty cycle ratio is increased. The current amplitude is reduced because the linear part of the plot of FIG. 1 ends at a lower drive current. The duty cycle is increased to maintain a desired optical output power.

The use of the control signal as explained above results in circuit operation with a high current amplitude and low duty cycle at low case temperatures, or at initial start-up. As the system heats up, the duty cycle will increase while the current amplitude decreases. However, the average optical output power remains constant.

It can be understood from FIG. 1 that an increased temperature will give rise to a reduction in efficiency, and this can result in increased semiconductor heating. Thus, a thermal runaway situation may arise in some situations. Protection for thermal runaway may thus be used as part of the laser control technique. The increased heating can be for example determined from the determined or estimated junction temperature, explained below.

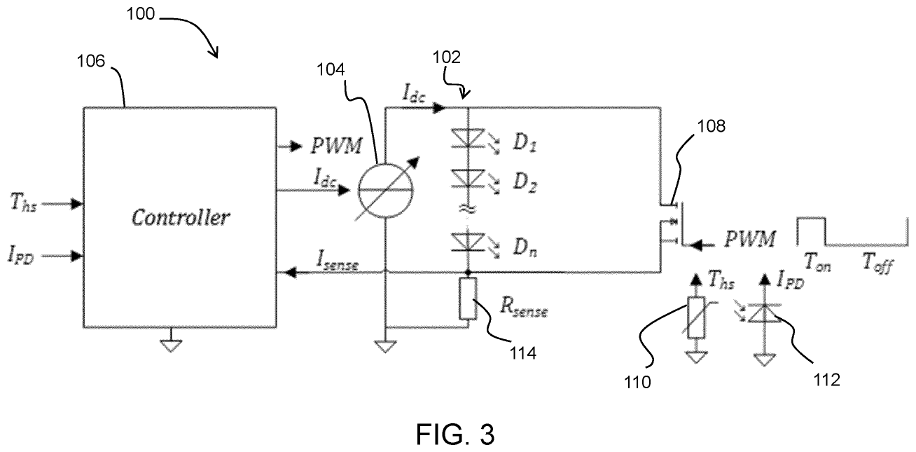

FIG. 3 shows a simplified block diagram of a laser circuit 100, comprising a laser device 102, in this case represented as a series connection of laser diodes D1 to Dn, and a current source 104 for delivering current to the laser device.

A controller 106 controls a current amplitude I_{dc} and a duty cycle of a pulse width modulation laser drive current delivered by the current source 104 to the laser device. A PWM signal “PWM” is generated which implements this duty cycle. The PWM signal is applied to a switching element 108 so that when the switching element is turned on, the current bypasses the laser device. However, there is minimal loss introduced by this current path. Preferably, the switching element is a transistor, more preferably a Metal Oxide Field Effect Transistor, MOSFET. Note that the switching element may instead be formed as a series switch between the current source and the laser device. Furthermore, if the current source is able to provide directly a PWM-based signal, there is no need for an external PWM switch. In such a case, the controller may be considered to be part of a current source circuit of the current source 104.

A sensor arrangement is used to provide a signal which enables determination or estimation of the junction temperature of the laser device 102. In the example shown, the sensor arrangement comprises a thermistor temperature sensor 110 which measures a case temperature of the laser device. This provides an indirect measurement of the junction temperature based sensing the temperature Tₕₛ of the heat sink.

Alternatively, the sensor arrangement may comprise an optical flux sensor, shown in FIG. 3 as photodiode 112, which generates a signal I_{PD} representing the optical output flux.

The thermal properties (power and heat sink properties) of the system may in this case be used as parameters stored in a register of the controller such that the junction temperature can be estimated by computation within the controller, from the measured optical output power and from these stored parameters.

In particular, the measured optical output power may be used in combination with data which characterizes the optical output power as a function of junction temperature for the particular device. This characterization information could for example have been obtained during the manufacturing process of the laser device itself or during the assembly and factory calibration of the overall laser circuit.

The junction temperature measurement is thus by an open-loop sensing system.

The use of a photodiode generating a detector current I_{PD} however means that efficiency can be optimized with a feedback loop. The efficiency can be derived from the measured optical output power and the drive conditions (current and voltage) which determine the electrical input power.

The forward voltage of a LED or laser is a given parameter so that only the current amplitude needs to be controlled. If the optical power is measured by means of a photo detector, the drive current does not necessarily need to be measured as optical output power can be measured. If a closed loop current controller is used, the current level can be set without the need to actually measure it.

The drive current is based on the control of the current source 104. However, a current amplitude measurement device may also be provided for measuring the laser device current. In the example shown, this is a current sense resistor 114, and the voltage across the current sense resistor is indicative of the current Iₛₑₙₛₑ.

The controller 106 estimates a junction temperature of the laser device and sets the amplitude and duty cycle of the laser drive current in dependence on the junction temperature. The controller 106 is thereby able to implement a maximum efficiency VCSEL drive scheme. As explained above, current sensing is not necessarily required if the optical output power is measured.

As a minimum, only the temperature estimation is needed, i.e. the temperature sensor and/or optical output sensor. The current drive conditions may be assumed to be known based on the current setting I_{dc} provided to the current sensor and the duty cycle. Information about the flux output as a function of temperature (i.e. the information of FIG. 1) is used by the controller, and this information may come from a factory calibration or from component datasheets. However, additional current sensing feedback may also be provided.

As the lasing threshold current as well as current density effects may be varying for each component, a self-learning cycle may be used during a factory calibration. In this way the controller knows the behavior of the laser component over various temperatures. This will also compensate for differences in the cooling interface quality.

Depending on the available sensing, a self-learning process may be used over the lifetime of the laser device in order to adapt to the aging effect of the semiconductor. This may for example use the sensed values to compare them against the expected values for the lasing threshold and lasing efficiency rollover. A self-learning process involves the use of a computer program having the ability to follow ageing trends and apply feedback or feedforward control signals to adapt the duty-cycle or current amplitude without scanning for the optimal efficiency operating point continuously or at each start-up/power-up.

The invention may be applied to any type of laser not only VCSELs, and including laser diodes.

The invention is of particular interest for low frequency operation. The operating frequency is for example in the range of 10 Hz to 100 kHz, typically in the range of 1 kHz to 20 kHz. The duty cycle may vary from 0.1 to 0.9, typically in the range of 0.5 to 0.9.

The invention may be used in laser-based lighting systems but also in other laser systems such as industrial laser based heating systems.

As discussed above, embodiments make use of a controller. The controller can be implemented in numerous ways, with software and/or hardware, to perform the various functions required. A processor is one example of a controller which employs one or more microprocessors that may be programmed using software (e.g., microcode) to perform the required functions. A controller may however be implemented with or without employing a processor, and also may be implemented as a combination of dedicated hardware to perform some functions and a processor (e.g., one or more programmed microprocessors and associated circuitry) to perform other functions.

Examples of controller components that may be employed in various embodiments of the present disclosure include, but are not limited to, conventional microprocessors, application specific integrated circuits (ASICs), and field-programmable gate arrays (FPGAs).

In various implementations, a processor or controller may be associated with one or more storage media such as volatile and non-volatile computer memory such as RAM, PROM, EPROM, and EEPROM. The storage media may be encoded with one or more programs that, when executed on one or more processors and/or controllers, perform the required functions. Various storage media may be fixed within a processor or controller or may be transportable, such that the one or more programs stored thereon can be loaded into a processor or controller.

Variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality.

The mere fact that certain measures are recited in mutually different dependent claims does not indicate that a combination of these measures cannot be used to advantage.

If the term “adapted to” is used in the claims or description, it is noted the term “adapted to” is intended to be equivalent to the term “configured to”.

Any reference signs in the claims should not be construed as limiting the scope.

1. A laser circuit, comprising:
a laser device;
a current source adapted to provide a current to the laser device, wherein the current has an amplitude and a duty cycle;
a controller for controlling the current source; and
a sensor arrangement for monitoring a signal enabling a junction temperature of the laser device to be estimated,
wherein the controller is adapted to:
estimate a junction temperature of the laser device;
set the amplitude of the current to the laser device in dependence on the junction temperature, and
set the duty cycle of the current to the laser device in dependence on a required power for the laser device.

2. The laser circuit of claim 1, wherein the current source comprising a switching element coupled in parallel with the laser device or in series with the laser device, wherein the switching element is arranged to control the duty cycle of the current to the laser device.

3. The laser circuit of claim 1, wherein the controller is adapted to control the current amplitude and the duty cycle of the pulse width modulation laser drive current to achieve a desired efficiency and a desired optical output power.

4. The laser circuit of claim 3, wherein the controller is adapted to control the current amplitude and the duty cycle of the pulse width modulation laser drive current to operate at an amplitude corresponding to a maximum efficiency and to operate at a duty cycle to deliver the desired optical output power.

5. The laser circuit of claim 1, wherein the sensor arrangement comprises a temperature sensor for measuring a case temperature of the laser device.

6. The laser circuit of claim 1, wherein the sensor arrangement comprises optical flux sensor for measuring an optical output power.

7. The laser circuit of claim 1, further comprising a current amplitude measurement device for measuring a laser device current.

8. The laser circuit of claim 1, wherein the controller is further adapted to determine the output power of the laser and to set the amplitude and duty cycle of the laser drive current further in dependence on the output power.

9. The laser circuit of claim 1, wherein the laser device comprises a vertical cavity surface emitting laser.

10. The laser circuit of claim 1, wherein the laser device comprises one or more laser diodes.

11. The laser circuit of claim 1 comprising a lighting circuit for delivering a constant light output power.

12. A method of controlling a laser device, comprising:
estimating a junction temperature of the laser device;
setting an amplitude of a pulse width modulation laser drive current in dependence on the junction temperature;
setting a duty cycle of the pulse width modulation laser drive current in dependence of a required power for the laser device, and
delivering the laser driver current to the laser device.

13. The method of claim 12, comprising controlling setting the current amplitude and the duty cycle of the pulse width modulation laser drive current to achieve a desired efficiency and a desired optical output power.

14. The method of claim 13, comprising setting the current amplitude and the duty cycle of the pulse width modulation laser drive current to operate at an amplitude corresponding to a maximum efficiency and to operate at a duty cycle to deliver the desired optical output power.

15. A computer program comprising computer program code means which is adapted, when said program is run on a computer, to implement the method of claim 12.
